(19) United States
(12) Patent Application Publication
(10) Pub. No.: US 2024/0407081 A1
(43) Pub. Date: Dec. 5, 2024

(54) ON-BOARD CHARGER

(71) Applicant: Delta Electronics (Shanghai) Co., Ltd., Shanghai (CN)

(72) Inventors: Suhua Chen, Shanghai (CN); Xiaolei Wang, Shanghai (CN); Peiai You, Shanghai (CN)

(21) Appl. No.: 18/417,914

(22) Filed: Jan. 19, 2024

(30) Foreign Application Priority Data
May 30, 2023 (CN) 202321352195.7
Nov. 2, 2023 (CN) 202311455636.0
Nov. 2, 2023 (CN) 202322967531.5

(51) Int. Cl. H05K 1/02; H05K 1/18

(52) U.S. Cl. CPC H05K 1/0272; H05K 1/181; H05K 2201/064; H05K 2201/10015; H05K 2201/1003; H05K 2201/10166; H05K 2201/10522

(57) ABSTRACT

The present disclosure provides an on-board charger. The on-board charger includes a housing, a connection channel, a circuit board assembly, and a plurality of electronic components. The housing includes an accommodation space. The accommodation space includes a heat dissipating area, the heat dissipating area includes an upper layer, a fluid channel layer, and a lower layer. A fluid channel is formed inside the fluid channel layer. The connection channel is in communication with the first fluid channel. The circuit board assembly includes an upper substrate and a lower substrate. A part of the upper substrate is disposed in the upper layer, and a part of the first lower substrate is disposed in the first lower layer. The plurality of electronic components are disposed corresponding to the circuit board assembly.

### CROSS-REFERENCE TO RELATED APPLICATION

This application claims priority to China Patent Application No. 202321352195.7, filed on May 30, 2023. This application claims priority to China Patent Application No. 202311455636.0, filed on Nov. 2,2023. This application claims priority to China Patent Application No. 202322967531.5, filed on Nov. 2, 2023. The entireties of the above-mentioned patent applications are incorporated herein by reference for all purposes.

### FIELD OF THE INVENTION

The present disclosure relates to a technical field of electric vehicle power, and more particularly to an on-board charger.

### BACKGROUND OF THE INVENTION

With the development of the electric vehicle power technology, integration and lightweight of on-board chargers have become mainstream demands in the market. The on-board chargers with high power density have better market prospects. Reasonable layout is particularly important to improve the power density and space utilization of the on-board charger.

The structure of conventional on-board charger is usually not compact enough, and the space inside the device is not fully utilized. Consequently, the disadvantages of large size and low power density are caused. In addition, the magnetic components of conventional on-board chargers are usually selected from existing product libraries. As a result, it is difficult for other components to match the magnetic components, so that the space utilization cannot be improved, and the heat dissipating performance is poor.

On the other hand, the conventional on-board charger usually includes a liquid cooling structure. The liquid cooling structure includes a fluid channel, an inlet tube, and an outlet tube. The fluid channel is in communication between the inlet tube and the outlet tube, and configured for allowing the liquid to flow through the electronic components inside the on-board charger, so that heat dissipation is performed. However, the inlet tube and the outlet tube are usually disposed outside the housing, and disposed adjacent to two sides of other connectors. Consequently, it is difficult to reduce the width of the on-board charger.

Therefore, there is a need of providing an on-board charger to obviate the drawbacks encountered from the prior arts.

### SUMMARY OF THE INVENTION

It is an objective of the present disclosure to provide an on-board charger, which achieves the advantages of reducing volume, improving space utilization, and enhancing the power density.

In accordance with an aspect of the present disclosure, there is provided an on-board charger. The on-board charger includes a housing, a connection channel, a circuit board assembly, and a plurality of electronic components. The housing includes a plurality of sidewalls. The plurality of sidewalls are connected with each other to define an accommodation space. The accommodation space includes a first heat dissipating area. The first heat dissipating area includes a first upper layer, a first fluid channel layer and a first lower layer. The first fluid channel layer is disposed between the first upper layer and the first lower layer and includes a first base, a first cover and a first fluid channel. The first cover covers the first base to form the first fluid channel. The connection channel is in communication with the first fluid channel. The connection channel and the first base are integrally formed into a one-piece structure. The circuit board assembly includes a first upper substrate and a first lower substrate. At least a part of the first upper substrate is disposed in the first upper layer, and at least a part of the first lower substrate is disposed in the first lower layer. The plurality of electronic components are disposed corresponding to the circuit board assembly.

In accordance with another aspect of the present disclosure, there is provided an on-board charger. The on-board charger includes a circuit board assembly, a housing, and a plurality of electronic components. The circuit board assembly includes a first upper substrate, a second upper substrate, a first lower substrate, and a second lower substrate. The housing having an accommodation space. The accommodation space includes a fluid channel dissipating area and a partition heat dissipating area. The fluid channel dissipating area includes a first upper layer, a fluid channel layer, and a first lower layer. The fluid channel layer is disposed between the first upper layer and the first lower layer. At least a part of the first upper substrate of the circuit board assembly is disposed in the first upper layer, and at least a part of the first lower substrate is disposed in the first lower layer. At least a part of the first upper substrate, the fluid channel layer and at least a part of the first lower substrate collectively form a first three-layer structure. The partition heat dissipating area is disposed adjacent to a side of the fluid channel heat dissipating area, and includes a second upper layer, a partition layer and a second lower layer. The partition layer is disposed between the second upper layer and the second lower layer. The second upper substrate is disposed in the second upper layer, and the second lower substrate is disposed in the second lower layer. The second upper substrate, the partition layer and the second lower substrate collectively form a second three-layer structure. The plurality of electronic components are disposed on the circuit board assembly, respectively, and are disposed corresponding to the first upper layer, the first lower layer, the second upper layer and the second lower layer.

### BRIEF DESCRIPTION OF THE DRAWINGS

FIG. 1 is a schematic perspective view illustrating an on-board charger according to a first embodiment of the present disclosure;

FIG. 2 is an exploded view illustrating the on-board charger of FIG. 1;

FIG. 3 is an exploded view in another angle of view illustrating the on-board charger of FIG. 1;

FIG. 4 is a cross-sectional view illustrating the on-board charger of FIG. 1;

FIG. 5 is an exploded view illustrating a housing, an inlet fluid connector, and an outlet fluid connector of the on-board charger of FIG. 1, wherein a first sidewall of the housing corresponding to the inlet channel and the outlet channel is shown in perspective;

FIG. 6 is a schematic perspective view illustrating a housing of an on-board charger according to a second embodiment of the present disclosure;

FIG. 7 is a schematic perspective view illustrating an on-board charger according to a third embodiment of the present disclosure;

FIG. 8 is a schematic perspective view illustrating an on-board charger according to a fourth embodiment of the present disclosure;

FIG. 9 is an exploded view illustrating a housing of an on-board charger of FIG. 8;

FIG. 10 is a cross-sectional view illustrating the on-board charger of FIG. 8;

FIG. 11 is an exploded view illustrating a housing, an inlet fluid connector, and an outlet fluid connector of the on-board charger of FIG. 8;

FIG. 12 is a cross-sectional view illustrating an on-board charger according to a fifth embodiment of the present disclosure;

FIG. 13 is an exploded view illustrating a housing of an on-board charger according to a sixth embodiment of the present disclosure;

FIG. 14 is an exploded view illustrating a housing of an on-board charger according to a seventh embodiment of the present disclosure, wherein a first cover, a second cover and a third cover are omitted; and

FIG. 15 is an exploded view illustrating a housing of an on-board charger according to an eighth embodiment of the present disclosure, wherein a first cover, a second cover and a third cover are omitted.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items. Alternatively, the word “about” means within an acceptable standard error of ordinary skill in the art-recognized average. In addition to the operation/working examples, or unless otherwise specifically stated otherwise, in all cases, all of the numerical ranges, amounts, values and percentages, such as the number for the herein disclosed materials, time duration, temperature, operating conditions, the ratio of the amount, and the like, should be understood as the word “about” decorator. Accordingly, unless otherwise indicated, the numerical parameters of the present invention and scope of the appended patent proposed is to follow changes in the desired approximations. At least, the number of significant digits for each numerical parameter should at least be reported and explained by conventional rounding technique is applied. Herein, it can be expressed as a range between from one endpoint to the other or both endpoints. Unless otherwise specified, all ranges disclosed herein are inclusive.

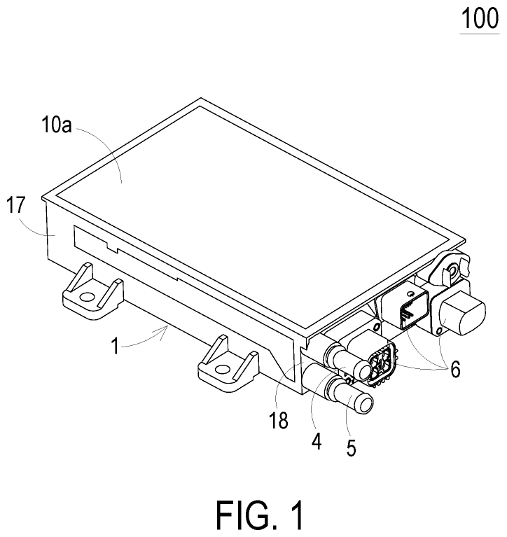

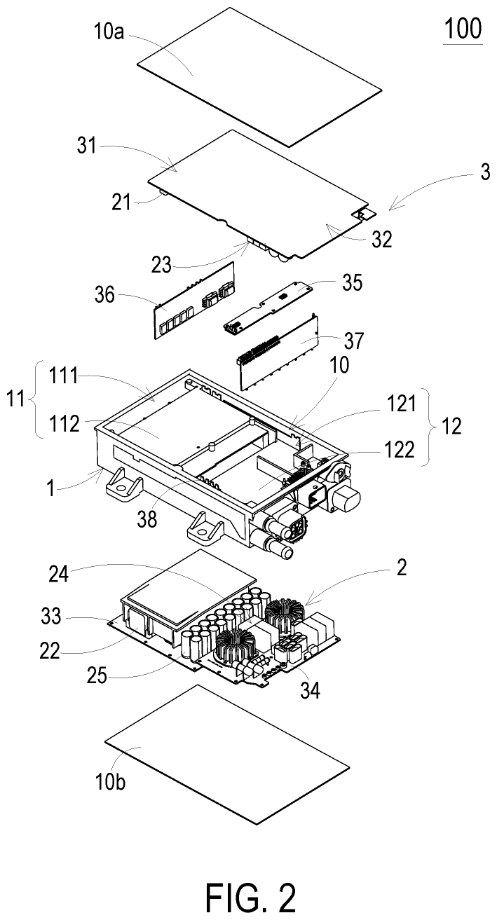

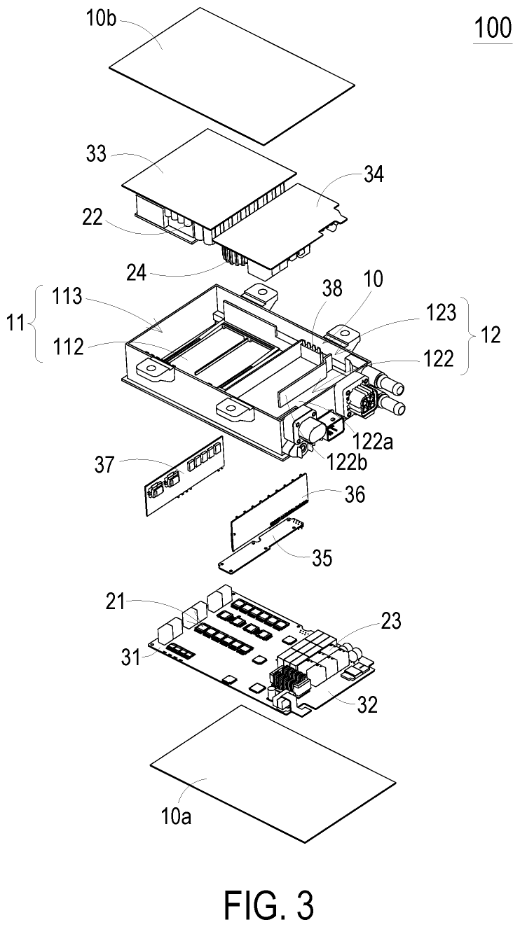

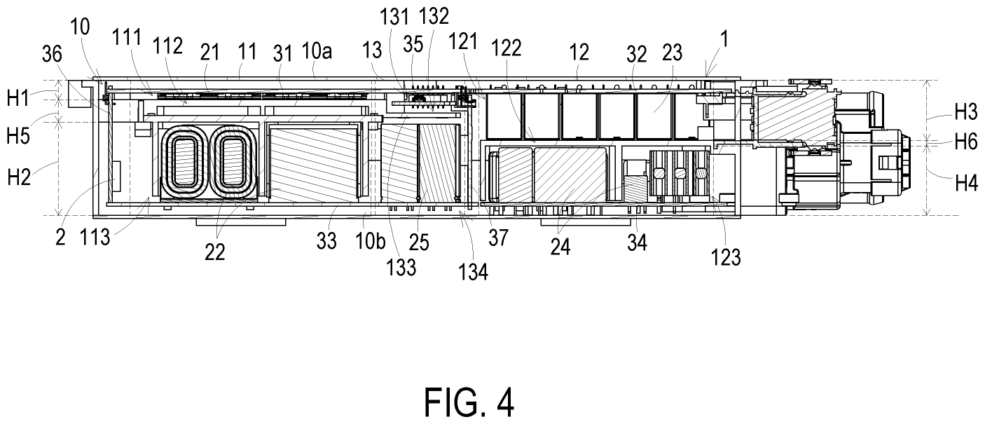

Please refer to FIG. 1 to FIG. 4, FIG. 1 is a schematic perspective view illustrating an on-board charger according to a first embodiment of the present disclosure, FIG. 2 is an exploded view illustrating the on-board charger of FIG. 1, FIG. 3 is an exploded view in another angle of view illustrating the on-board charger of FIG. 1, and FIG. 4 is a cross-sectional view illustrating the on-board charger of FIG. 1. The on-board charger 100 of the first embodiment includes a housing 1, a plurality of electronic components 2 and a circuit board assembly 3. The circuit board assembly 3 includes a first upper substrate 31, a second upper substrate 32, a first lower substrate 33, and a second lower substrate 34. An accommodation space 10 is formed in the housing 1. The accommodation space 10 includes a fluid channel dissipating area 11 (hereinafter also referred to as a first heat dissipating area) and a partition heat dissipating area 12 (hereinafter also referred to as a second heat dissipating area). The fluid channel heat dissipating area 11 includes a first upper layer 111, a first fluid channel layer 112 and a first lower layer 113. The first fluid channel layer 112 is disposed between the first upper layer 111 and the first lower layer 113. At least a part of the first upper substrate 31 of the circuit board assembly 3 is disposed in the first upper layer 111. At least a part of the first lower substrate 33 is disposed in the first lower layer 113. At least a part of the first upper substrate 31, the first fluid channel layer 112 and at least a part of the first lower substrate 33 collectively form a first multi-layer structure, such as a first three-layer structure. The partition heat dissipating area 12 is disposed at a side of the fluid channel heat dissipating area 11, and includes a second upper layer 121, a partition layer 122 and a second lower layer 123. The partition layer 122 is disposed between the second upper layer 121 and the second lower layer 123. The second upper substrate 32 is disposed in the second upper layer 121. The second lower substrate 34 is disposed in the second lower layer 123. The second upper substrate 32, the partition layer 122 and the second lower substrate 34 collectively form a second multi-layer structure, such as a second three-layer structure. The plurality of electronic components 2 are disposed on the circuit board assembly 3, and are disposed corresponding to the first upper layer 111, the first lower layer 113, the second upper layer 121 and the second lower layer 123, respectively. The first fluid channel layer 112 is configured for conducting a liquid-cooling heat dissipation to the plurality of electronic components 2 disposed in the first upper layer 111 and the first lower layer 113. The partition layer 122 is configured for conducting a partition-cooling heat dissipation to the plurality of electronic components 2 disposed in the second upper layer 121 and the second lower layer 123. Since the plurality of electronic components 2 are disposed in the fluid channel heat dissipating area 11 and the partition heat dissipating area 12 according to different heat dissipating requirements, respectively, the efficiency of heat dissipation is enhanced. The fluid channel heat dissipating area 11 of the present embodiment includes the first three-layer structure, and the plurality of electronic components 2 are disposed in the first upper layer 111 and the first lower layer 113 according to the height or the volume thereof, so that the space utilization is enhanced, the volume is reduced and the power density is increased. The partition heat dissipating area 12 of the present embodiment includes the second three-layer structure, and the plurality of electronic components 2 are disposed in the second upper layer 121 and the second lower layer 123 according to the height or the volume thereof, so that the space utilization is enhanced, the volume is reduced and the power density is increased.

As shown in FIG. 4, in an embodiment, the first upper layer 111 of the fluid channel heat dissipating area 11 has a first height H1, and the first lower layer 113 has a second height H2. The second upper layer 121 of the partition heat dissipating area 12 has a third height H3, and the second lower layer 123 has a fourth height H4. The second height H2 of the fluid channel heat dissipating area 11 is greater than the first height H1. The third height H3 is greater than the first height H1, and less than the second height H2. The fourth height H4 is greater than the first height H1, and less than the second height H2. According to the height of each of the electronic components 2, the electronic components 2 are disposed in the first upper layer 111, the first lower layer 113, the second upper layer 121 and the second lower layer 123 having different heights, respectively. In other words, the electronic components 2 disposed in the same layer have similar heights, so that the space of the first upper layer 111, the first lower layer 113, the second upper layer 121 and the second lower layer 123 are effectively utilized. Consequently, the space utilization is enhanced, the volume is reduced and the power density is increased.

Moreover, as shown in FIG. 4, in an embodiment, the first fluid channel layer 112 has a fluid channel layer height H5, and the partition layer 122 has a partition layer height H6. The sum of the first height H1, the fluid channel layer height H5 and the second height H2 is similar to or equal to the sum of the third height H3, the partition layer height H6 and the fourth height H4. In other words, the height of the fluid channel heat dissipating area 11 is similar to or equal to the height of the partition heat dissipating area 12, so that the space formed by the height difference between the fluid channel heat dissipating area 11 and the partition heat dissipating area 12 is reduced, the space utilization is enhanced, the volume is reduced and the power density is increased.

As shown in FIG. 4, in an embodiment, the housing 1 includes an upper cover 10a and a lower cover 10b. The upper cover 10a covers the top of the housing 1, and the lower cover 10b covers the bottom of the housing 1. The fluid channel heat dissipating area 11 is disposed adjacent to the upper cover 10a and the lower cover 10b. The partition heat dissipating area 12 is disposed adjacent to the upper cover 10a and the lower cover 10b. The fluid channel heat dissipating area 11 is the first three-layer structure formed by at least a part of the first upper substrate 31, the first fluid channel layer 112 and at least a part of the first lower substrate 33. The partition heat dissipating area 12 is the second three-layer structure formed by the second upper substrate 32, the partition layer 122 and the second lower substrate 34. In other words, the fluid channel heat dissipating area 11 and the partition heat dissipating area 12 disposed between the upper cover 10a and the lower cover 10b are three-layer structures, so that the space utilization is enhanced, the volume is reduced and the power density is increased.

As shown in FIG. 1 to FIG. 4, in the present embodiment, the first upper substrate 31 and the second upper substrate 32 are integrally formed into a one-piece circuit board, and the first lower substrate 33 and the second lower substrate 34 are two independent circuit boards disposed apart from each other, but not limited thereto. In an embodiment, the first upper substrate 31 and the second upper substrate 32 are two independent circuit boards. In an embodiment, the first lower substrate 33 and the second lower substrate 34 are integrally formed into a one-piece circuit board.

In the present embodiment, the circuit board assembly 3 includes a busbar 38. The busbar 38 is disposed in the accommodation space 10 of the housing 1, and located in the partition heat dissipating area 12. An end of the busbar 38 is electrically connected with the second upper substrate 32, and the other end of the busbar 38 is electrically connected with the second lower substrate 34. Consequently, the second upper substrate 32 and the second lower substrate 34 are electrically connected with each other through the busbar 38.

As shown in FIG. 2 to FIG. 4, in the present embodiment, the accommodation space 10 of the on-board charger 100 includes a middle area 13. The fluid channel heat dissipating area 11 and the partition heat dissipating area 12 are disposed at two opposite sides of the middle area 13, respectively. The middle area 13 includes a third upper layer 131, a third middle layer 132, a middle partition 133 and a third lower layer 134 arranged in sequence. The circuit board assembly 3 includes a middle substrate 35. The middle substrate 35 is disposed in the third middle layer 132. A part of the first upper substrate 31 is disposed in the third upper layer 131. A part of the first lower substrate 33 is disposed in the third lower layer 134. The middle area 13 is a third multi-layer structure formed by a part of the first upper substrate 31, the middle substrate 35, the middle partition 133 and a part of the first lower substrate 33, such as a four-layer structure. The middle partition 133 is configured for conducting a partition heat dissipation to the electronic components 2 disposed in the third lower layer 134. In an embodiment, the electronic component 2 disposed in the third lower layer 134 is an aluminum electrolytic capacitor. Due to the arrangement of the middle area 13, the space inside the housing 1 are effectively utilized, and the space utilization is enhanced, the volume is reduced and the power density is increased. In an embodiment, the middle partition 133 is extend from the first fluid channel layer 112 of the fluid channel heat dissipating area 11 toward the middle area 13, in other words, the middle partition 133 and the first fluid channel layer 112 are integrally formed into a one-piece structure, but not limited thereto.

As shown in FIG. 2 to FIG. 4, in the present embodiment, the circuit board assembly 3 includes a first lateral substrate 36. The first lateral substrate 36 is disposed in the accommodation space 10, located at a side of the fluid channel heat dissipating area 11, and perpendicularly connected between the first upper substrate 31 and the first lower substrate 33. The first upper substrate 31 and the first lower substrate 33 are electrically connected with each other through the first lateral substrate 36, so that the accommodation space 10 inside the housing 1 is effectively utilized, and the space utilization is enhanced, the volume is reduced and the power density is increased. In the present embodiment, some of the plurality of electronic components 2 are disposed on the first lateral substrate 36 for enhancing the space utilization and increasing the power density.

As shown in FIG. 2 to FIG. 4, in the present embodiment, the circuit board assembly 3 includes a second lateral substrate 37. The second lateral substrate 37 is disposed in the accommodation space 10, located between the middle area 13 and the partition heat dissipating area 12, and perpendicularly connected between the first upper substrate 31 and the first lower substrate 33. The first upper substrate 31 and the first lower substrate 33 are electrically connected with each other through the second lateral substrate 37. The middle substrate 35 is electrically connected with the first upper substrate 31. In the present embodiment, the third multi-layer structure, such as a four-layer structure, is formed by at least a part of the first upper substrate 31, the middle substrate 35, the middle partition 133 and the first lower substrate 33, so that the space inside the middle area 13 is effectively utilized, the space utilization is enhanced and the power density is increased. In an embodiment, some of the plurality of the electronic components 2 are disposed on the second lateral substrate 37 and/or the middle substrate 35 for enhancing the space utilization and increasing the power density.

As shown in FIG. 2 to FIG. 4, in the present embodiment, the plurality of electronic components 2 include a first group 21, a second group 22, a third group 23, a fourth group 24 and a fifth group 25. The first group 21 is disposed on the first upper substrate 31, and corresponding to the first upper layer 111. In the present embodiment, the first group 21 includes the electronic components having lower height and higher heat dissipating requirements, for example but not limited to include at least one power component. In one embodiment, the at least one power component is a power transistor, wherein the power transistor can be either a discrete type or an integrated type. The second group 22 is disposed on the first lower substrate 33, and corresponding to the first lower layer 113. In the present embodiment, the second group 22 includes the electronic components having higher height and higher heat dissipating requirements, for example but not limited to include a transformer and an inductor. The third group 23 is disposed on the second upper substrate 32, and corresponding to the second upper layer 121. In the present embodiment, the third group 23 includes the electronic components having lower heat dissipating requirements, for example but not limited to include at least one magnetic components. In one embodiment, the at least one magnetic component includes a common mode inductor and a differential mode inductor. The fourth group 24 is disposed on the second lower substrate 34, and corresponding to the second lower layer 123. In the present embodiment, the fourth group 24 includes the electronic components having lower heat dissipating requirements, for example but not limited to include a capacitor and a common mode inductor. The fifth group 25 is disposed on the first lower substrate 33, and corresponding to the third lower layer 134. In one embodiment, the fifth group 25 includes an aluminum electrolytic capacitor. As mentioned above, the electronic components 2 are arranged and disposed in the layers and the areas according to the heights and heat dissipating requirements thereof, so that the accommodation space 10 inside the housing 1 is effectively utilized, the space utilization is enhanced, the volume is reduced and the power density is increased.

As shown in FIG. 2 to FIG. 4, in an embodiment, the second group 22 is disposed on the first lower substrate 33 toward the first fluid channel layer 112, the third group 23 is disposed on the second upper substrate 32 toward the partition layer 122, and the fourth group 24 is disposed on the second lower substrate 34 toward the partition layer 122.

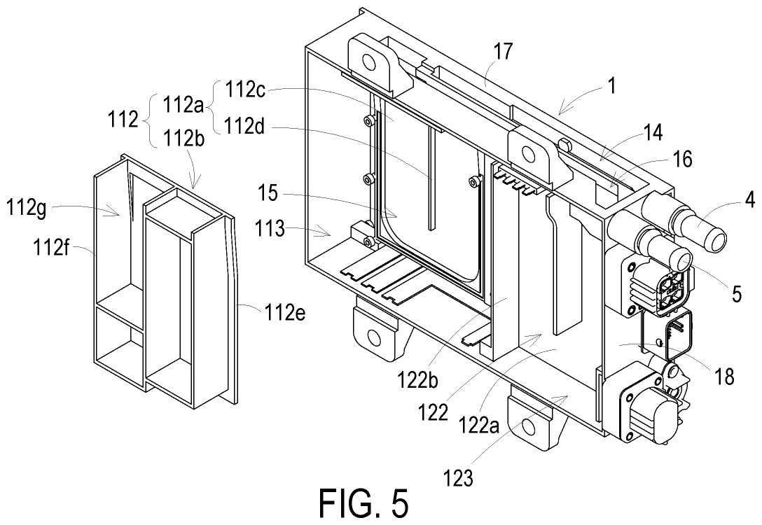

FIG. 5 is an exploded view illustrating a housing, an inlet fluid connector, and an outlet fluid connector of the on-board charger of FIG. 1, wherein a first sidewall of the housing 1 corresponding to the inlet channel and the outlet channel is shown in perspective. As shown in FIG. 1 and FIG. 5, the on-board charger 100 includes an inlet fluid connector 4 and an outlet fluid connector 5. The on-board charger 100 includes an inlet channel 14, a first fluid channel 15 and an outlet channel 16. The inlet channel 14 and the outlet channel 16 are formed inside the first sidewall 17 of the housing 1. The connection channel includes the inlet channel 14 and the outlet channel 16. The first fluid channel 15 is formed in the first fluid channel layer 112. The inlet channel 14 is in fluid communication between the first fluid channel 15 and the inlet fluid connector 4. The outlet channel 16 is in fluid communication between the first fluid channel 15 and the outlet fluid connector 5. In other words, a fluid flowing path is formed by the inlet fluid connector 4, the inlet channel 14, the first fluid channel 15, the outlet channel 16 and the outlet fluid connector 5 connected in sequence. The fluid flowing path is configured for a cooling fluid to pass therethrough, so that the cooling fluid is used to perform the heat dissipation process to the electronic components 2 disposed in the fluid channel heat dissipating area 11. In the present embodiment, the cooling fluid for example is water. Since the inlet channel 14 and the outlet channel 16 are formed inside the first sidewall 17 of the housing 1, additional flow channels are omitted to save the space, so that the space utilization is enhanced and the power density is increased.

As shown in FIG. 1 and FIG. 5, in the present embodiment, the first fluid channel layer 112 includes a first base 112a and a first cover 112b. The first base 112a is extended form the first sidewall 17 toward the fluid channel heat dissipating area 11, in other words, the first base 112a and the first sidewall 17 are integrally formed into a one-piece structure. In an embodiment, the first base 112a is disposed perpendicular to the first sidewall 17. The first base 112a includes a groove 112c and a separation part 112d. The groove 112c is disposed toward the first lower layer 113. The separation part 112d is disposed in the groove 112c. The groove 112c is divided into two channels which are interconnected by the separation part 112d, and the two channels are in fluid communication with the inlet channel 14 and the outlet channel 16, respectively. The first cover 112b covers the groove 112c, so that the two channels are sealed to form the first fluid channel 15.

As shown in FIG. 1, FIG. 4, and FIG. 5, in the present embodiment, the first cover 112b of the first fluid channel layer 112 of the housing 1 is disposed toward the first lower layer 113 of the fluid channel heat dissipating area 11, and includes a substrate 112e and a plurality of partitions 112f. A surface of the substrate 112e covers and seals the groove 112c of the first base 112a. The plurality of partitions 112f are extended from the other surface of the substrate 112e toward the first lower layer 113. At least one accommodation part 112g is defined by the substrate 112e and the plurality of partitions 112f. The electronic components 2 disposed in the first lower layer 113 are modularly disposed in the at least one accommodation part 112g of the first cover 112b. Since the electronic components 2 are modularly disposed in the at least one accommodation part 112g, the area and integrity of heat dissipating are increased, and more electronic components 2 can be disposed in the on-board charger 100. Consequently, the space utilization is enhanced and the power density is increased.

As shown in FIG. 1, FIG. 4 and FIG. 5, in the present embodiment, the housing 1 includes a second sidewall 18. A side of the second sidewall 18 is in connection with a side of the first sidewall 17. In the present embodiment, the on-board charger 100 includes at least one electrical connector 6. The at least one electrical connector 6 penetrates through the second sidewall 18 of the housing 1, and electrically connected with the circuit board assembly 3, so that the transmission of electrical energy and signals is performed. The inlet fluid connector 4 and the outlet fluid connector 5 are disposed side by side on the second sidewall 18 and disposed adjacent to the at least one electrical connector 6. The inlet fluid connector 4 is in fluid communication with the inlet channel 14 disposed in the first sidewall 17, and the outlet fluid connector 5 is in fluid communication with the outlet channel 16 disposed in the first sidewall 17. Since the inlet fluid connector 4 and the outlet fluid connector 5 are disposed side by side on the same side of the second sidewall 18, the width of the second sidewall 18 is reduced, the space utilization is enhanced and the power density is increased.

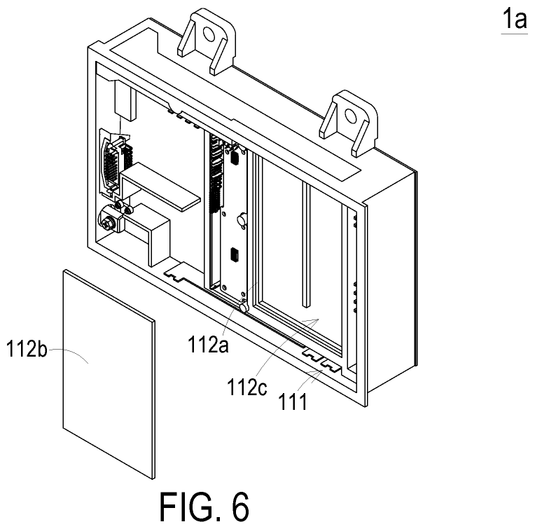

FIG. 6 is a schematic perspective view illustrating a housing of an on-board charger according to a second embodiment of the present disclosure. The housing la of the present embodiment is similar to the housing 1 shown in FIG. 1 to FIG. 5. Component parts and elements corresponding to those of the first embodiment are designated by identical numeral references, and detailed descriptions thereof are omitted. Different from the housing 1 shown in FIG. 1 to FIG. 5, the groove 112c of the first base 112a of the first fluid channel layer 112 of the housing la is disposed toward the first upper layer 111. The first cover 112b is a flat plate structure, is disposed toward the first upper layer 111, covers the first base 112a, and seals the groove 112c by a friction stir welding process, so that the first fluid channel 15 is sealed. Consequently, the process is simple and the reliability of the on-board charger is enhanced.

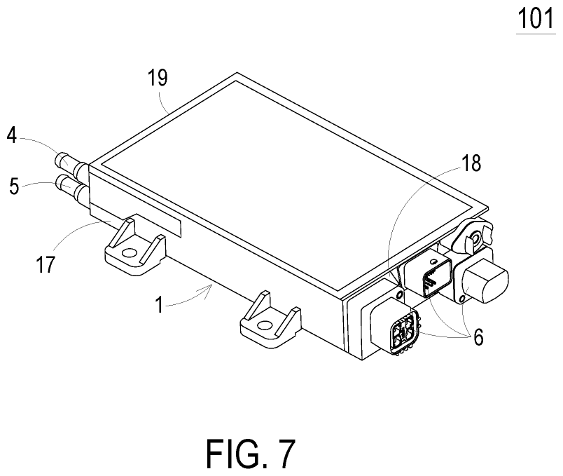

FIG. 7 is a schematic perspective view illustrating an on-board charger according to a third embodiment of the present disclosure. The on-board charger 101 of the present embodiment is similar to the on-board charger 100 shown in FIG. 1 to FIG. 5. Component parts and elements corresponding to those of the first embodiment are designated by identical numeral references, and detailed descriptions thereof are omitted. Different from the on-board charger 100 shown in FIG. 1 to FIG. 5, the at least one electrical connector 6 of the on-board charger 101 of the present embodiment is disposed on the second sidewall 18 of the housing 1, and electrically coupled with the circuit board assembly 3. The inlet fluid connector 4 and the outlet fluid connector 5 of the on-board charger 101 are disposed side by side on the third sidewall 19 of the housing 1. The third sidewall 19 is in connection with the first sidewall 17, and located at a side of the housing 1 opposite to the second sidewall 18 having the at least one electrical connector 6. The inlet fluid connector 4 and the outlet fluid connector 5 are disposed on a side of the housing 1 opposite to the side of the housing 1 that the at least one electrical connector 6 located. Consequently, the width of the housing 1 is reduced, the volume is reduced, and the power density is increased.

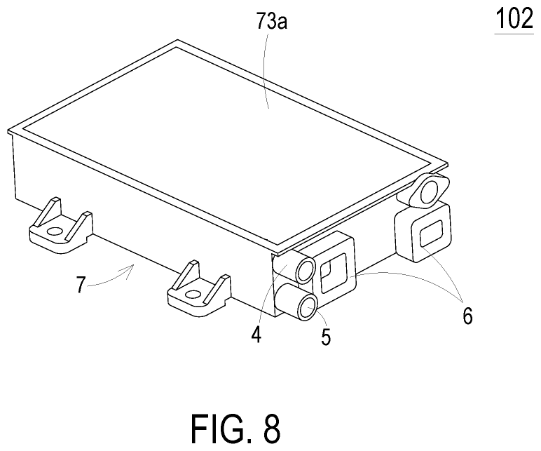

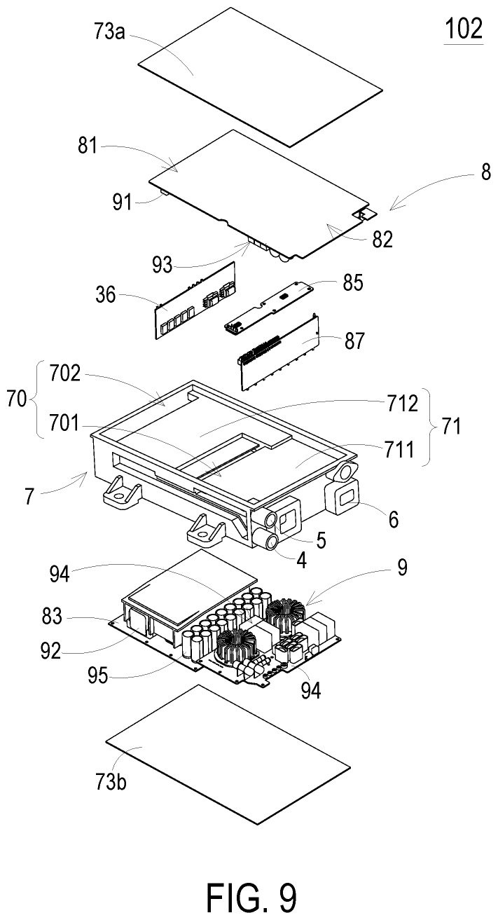

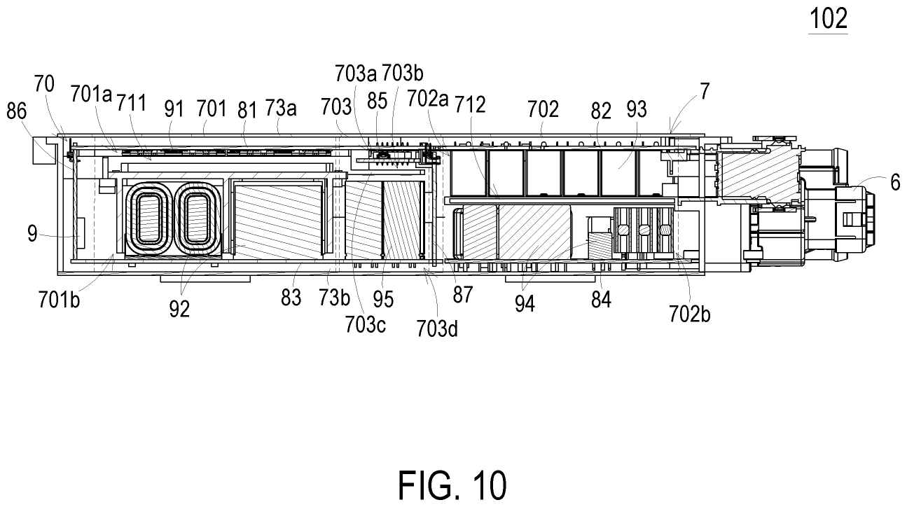

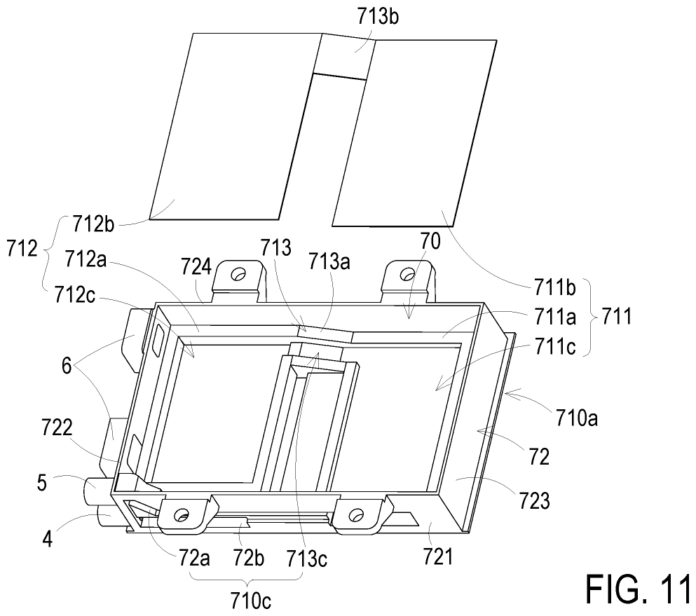

FIG. 8 is a schematic perspective view illustrating an on-board charger according to a fourth embodiment of the present disclosure, FIG. 9 is an exploded view illustrating a housing of an on-board charger of FIG. 8, FIG. 10 is a cross-sectional view illustrating the on-board charger of FIG. 8, and FIG. 11 is an exploded view illustrating a housing, an inlet fluid connector, and an outlet fluid connector of the on-board charger of FIG. 8. As shown in FIG. 8 to FIG. 11, the on-board charger 102 of the fourth embodiment of the present disclosure includes a housing 7, a circuit board assembly 8 and a plurality of electronic components 9. The housing 7 includes a plurality of sidewalls 72. The plurality of sidewalls 72 are connected with each other to define an accommodation space 70. The accommodation space 70 includes a first heat dissipating area 701 and a second heat dissipating area 702. The first heat dissipating area 701 is disposed at a side of the second heat dissipating area 702. The first heat dissipating area 701 includes a first upper layer 701a, a first lower layer 701b and a first fluid channel layer 711. The first fluid channel layer 711 includes a first base 711a, a first cover 711b and a first fluid channel 711c. The first cover 711b covers the first base 711a to form the first fluid channel 711c. More specifically, the first fluid channel 711c, for example, is formed in the first base 711a, and the first cover 711b covers the first base 711a to seal the first fluid channel 711c. The first fluid channel layer 711 is disposed corresponding to the first heat dissipating area 701, and divides the first heat dissipating area 701 into the first upper layer 701a and the first lower layer 701b. The second heat dissipating area 702 includes a second upper layer 702a, a second lower layer 702b and a second fluid channel layer 712. The second fluid channel layer 712 includes a second base 712a, a second cover 712b and a second fluid channel 712c. The second cover 712b covers the second base 712a to form the second fluid channel 712c. More specifically, the second fluid channel 712c, for example, is formed in the second base 712a, and the second cover 712b covers the second base 712a to seal the second fluid channel 712c. The second fluid channel layer 712 is disposed corresponding to the second heat dissipating area 702, and divides the second heat dissipating area 702 into the second upper layer 702a and the second lower layer 702b. In the present embodiment, the on-board charger 102 includes at least one connection channel 710c. The at least one connection channel 710c for example includes an inlet channel 72a and an outlet channel 72b. The inlet channel 72a and the outlet channel 72b are disposed side by side inside a first sidewall 721 of the plurality of sidewalls 72 of the housing 7. The first base 711a is extended from the first sidewall 721 toward the first heat dissipating area 701, in other words, the first base 711a and the first sidewall 721 are integrally formed into a one-piece structure. In an embodiment, the first base 711a, for example, is disposed perpendicular to the first sidewall 721. The second base 712a is extended from the first sidewall 721 toward the second heat dissipating area 702, in other words, the second base 712a and the first sidewall 721 are integrally formed into a one-piece structure. In an embodiment, the second base 712a, for example, is disposed perpendicular to the first sidewall 721. The inlet channel 72a is in fluid communication with the second fluid channel 712c, and the outlet channel 72b is in fluid communication with the first fluid channel 711c. The circuit board assembly 8 includes a first upper substrate 81, a second upper substrate 82, a first lower substrate 83 and a second lower substrate 84. At least a part of the first upper substrate 81 is disposed in the first upper layer 701a. At least a part of the first lower substrate 83 is disposed in the first lower layer 701b. At least a part of the first upper substrate 81, the first fluid channel layer 711 and at least a part of the first lower substrate 83 collectively form a first multi-layer structure, such as a first three-layer structure. The second upper substrate 82 is disposed in the second upper layer 702a. The second lower substrate 84 is disposed in the second lower layer 702b. The second upper substrate 82, the second fluid channel layer 712 and the second lower substrate 84 collectively form a second multi-layer structure, such as a second three-layer structure. The plurality of electronic components 9 are disposed on the circuit board assembly 8, respectively, and are disposed corresponding to the first upper layer 701a, the first lower layer 701b, the second upper layer 702a and the second lower layer 702b. The first fluid channel layer 711 and the second fluid channel layer 712 are configured for conducting a heat dissipation to the plurality of electronic components 9. The first fluid channel layer 711 is configured for conducting the heat dissipation to the electronic components 9 disposed in the first upper layer 701a and the first lower layer 701b, and the second fluid channel layer 712 is configured for conducting the heat dissipation to the electronic components 9 disposed in the second upper layer 702a and the second lower layer 702b. Due to the arrangement of the first fluid channel layer 711 and the second fluid channel layer 712, the heat dissipating efficiency is enhanced. Since the first heat dissipating area 701 of the present embodiment includes the first multi-layer structure, the electronic components 9 are disposed in the first upper layer 701a and the first lower layer 701b according to the height and volume thereof. Consequently, the space utilization is enhanced, the volume is reduced and the power density is increased. Since the second heat dissipating area 702 of the present embodiment includes the second multi-layer structure, the electronic components 9 are disposed in the second upper layer 702a and the second lower layer 702b according to the height and volume thereof. Consequently, the space utilization is enhanced, the volume is reduced and the power density is increased.

As shown in FIG. 8 to FIG. 11, in the present embodiment, the on-board charger 102 includes an inlet fluid connector 4 and an outlet fluid connector 5. The inlet channel 72a is in fluid communication with the inlet fluid connector 4, and the outlet channel 72b is in communication with the outlet fluid connector 5. The first fluid channel 711c is in fluid communication with the outlet channel 72b, the second fluid channel 712c is in fluid communication with the inlet channel 72a, and the first fluid channel 711c is in fluid communication with the second fluid channel 712c. In other words, a fluid flowing path is formed by the inlet fluid connector 4, the inlet channel 72a, the second fluid channel 712c, the first fluid channel 711c, the outlet channel 72b and the outlet fluid connector 5 connected in sequence. The fluid flowing path is configured for a cooling fluid to pass therethrough, so that the cooling fluid is used to perform the heat dissipation to the electronic components 2 disposed in the first heat dissipating area 701 and the second heat dissipating area 702. In the present embodiment, the cooling fluid is for example, but not limited to water. Since the inlet channel 72a and the outlet channel 72b are formed inside the first sidewall 721 of the housing 7, additional flow channels are omitted to save the space. Consequently, the space utilization is enhanced, and the power density is increased.

As shown in FIG. 9 and FIG. 11, in the present embodiment, the accommodation space 70 includes a third fluid channel layer 713. In an embodiment, the third fluid channel layer 713 is disposed adjacent to one of the sidewalls 72 of the housing 7, such as the fourth sidewall 724. The fourth sidewall 724 is disposed opposite to the first sidewall 721. The third fluid channel layer 713 is disposed between the first fluid channel layer 711 and the second fluid channel layer 712, and includes a third base 713a, a third cover 713b and a third fluid channel 713c. The third cover 713b covers the third base 713a to form the third fluid channel 713c of the third fluid channel layer 713. More specifically, the third fluid channel 713c, for example, is formed in the third base 713a, and the third cover 713b covers the third base 713a to seal the third fluid channel 713c. The third fluid channel 713c is in fluid communication between the first fluid channel 711c and the second fluid channel 712c to form a fluid flowing path. In the present embodiment, the at least one connection channel 710c includes the third fluid channel 713c.

As shown in FIG. 8 to FIG. 11, in the present embodiment, the plurality of sidewalls 72 of the housing 7 of the on-board charger 102 include a first sidewall 721, a second sidewall 722, a third sidewall 723 and a fourth sidewall 724. The first sidewall 721, the second sidewall 722, the third sidewall 723 and the fourth sidewall 724 are in connection with each other to form the accommodation space 70. The first base 711a, the second base 712a and the third base 713a are integrally formed into a first one-piece structure 710a. In an embodiment, the plurality of the sidewalls 72, the first base 711a, the second base 712a and the third base 713a are formed by a metal material. In the present embodiment, the first cover 711b, the second cover 712b and the third cover 713b are integrally formed into a second one-piece structure 710b. In an embodiment, the first cover 711b, the second cover 712b and the third cover 713b are formed by a metal material. The second one-piece structure 710b formed by the first cover 711b, the second cover 712b and the third cover 713b covers on the first one-piece structure 710a formed by the first base 711a, the second base 712a and the third base 713a, so as to seal the first fluid channel 711c, the second fluid channel 712c and the third fluid channel 713c. In the present embodiment, the metal material is at least one of ADC3 aluminum alloy and ADC12 aluminum alloy, so that the advantages of enhancing fluid mobility, thermal conductivity, and corrosion resistance are achieved.

In an embodiment, the plurality of sidewalls 72, the first fluid channel layer 711, the second fluid channel layer 712 and the third fluid channel layer 713 are integrally formed into a one-piece structure manufactured by the metal material. In other words, the first sidewall 721, the second sidewall 722, the third sidewall 723 and the fourth sidewall 724 of the housing 7, the first base 711a, the first cover 711b, the second base 712a, the second cover 712b, the third base 713a and the third cover 713b are integrally formed into a one-piece structure, but not limited thereto.

As shown in FIG. 9 and FIG. 11, in the present embodiment, the inlet fluid connector 4 and the outlet fluid connector 5 are disposed side by side on the second sidewall 722 of the housing 7, and the second sidewall 722 is adjacently connected with the first sidewall 721. In some other embodiments, the positions of the inlet fluid connector 4 and the outlet fluid connector 5 are interchangeable, and are not limited thereto. In an embodiment, the inlet fluid connector 4 and the outlet fluid connector 5 are disposed side by side on the third sidewall 723 of the housing 7, and the third sidewall 723 is adjacently connected with the first sidewall 721. The second sidewall 722 and the third sidewall 723 are disposed opposite to each other.

As shown in FIG. 9 and FIG. 11, in the present embodiment, the first fluid channel layer 711 and the second fluid channel layer 712 are non-coplanar, and the position of the second fluid channel layer 712 is higher than the position of the first fluid channel layer 711. The second fluid channel layer 712 is inclined toward the first fluid channel layer 711. Since the first fluid channel layer 711 and the second fluid channel layer 712 are non-coplanar, the first upper layer 701a, the first lower layer 701b, the second upper layer 702a and the second lower layer 702b have different heights, and the electronic components 9 are disposed in the first upper layer 701a, the first lower layer 701b, the second upper layer 702a and the second lower layer 702b according to the heights and volume thereof. Consequently, the space utilization is enhanced, the volume is reduced and the power density is increased. In addition, since the first fluid channel layer 711 and the second fluid channel layer 712 are non-coplanar, the fluid flows from the second fluid channel layer 712 having higher position to the first fluid channel layer 711 having lower position easily. Consequently, the fluid mobility is enhanced. In some other embodiments, the position of the first fluid channel layer 711 is higher than the position of the second fluid channel layer 712, and the first fluid channel layer 711 is inclined toward the second fluid channel layer 712, but not limited thereto. In an embodiment, preferably but not exclusively, the first fluid channel layer 711, the second fluid channel layer 712 and the third fluid channel layer 713 are coplanar.

As shown in FIG. 9 and FIG. 10, in the present embodiment, the housing 7 of the on-board charger 102 includes an upper cover 73a and a lower cover 73b. The upper cover 73a covers the top of the housing 7, and the lower cover 73b covers the bottom of the housing 7. The first heat dissipating area 701 is disposed adjacent to the upper cover 73a and the lower cover 73b. The second heat dissipating area 702 is disposed adjacent to the upper cover 73a and the lower cover 73b. The first heat dissipating area 701 and the second heat dissipating area 702 disposed between the upper cover 73a and the lower cover 73b are multi-layer structures, so that the space utilization is enhanced, the volume is reduced and the power density is increased. In an embodiment, the upper cover 73a and the lower cover 73b are at least one of ADC3 aluminum alloy and ADC12 aluminum alloy, respectively.

As shown in FIG. 9 and FIG. 10, in the present embodiment, the first upper substrate 81 and the second upper substrate 82 of the circuit board assembly 8 are integrally formed into a one-piece circuit board, and the first lower substrate 83 and the second lower substrate 84 are two independent circuit boards disposed apart from each other, but not limited thereto. In an embodiment, the first upper substrate 81 and the second upper substrate 82 are two independent circuit boards. In an embodiment, the first lower substrate 83 and the second lower substrate 84 are integrally formed into a one-piece circuit board.

As shown in FIG. 10, in the present embodiment the on-board charger 102 includes at least one electrical connector 6. The at least one electrical connector 6 penetrates through the second sidewall 722 of the housing 7, and is electrically connected with the circuit board assembly 8, so that the transmission of electrical energy and signals is performed. In an embodiment, the at least one electrical connector 6 penetrates through the third sidewall 723 of the housing 7.

As shown in FIG. 9 and FIG. 10, in the present embodiment, the accommodation space 70 includes a middle area 703. The first heat dissipating area 701 and the second heat dissipating area 702 are respectively disposed at opposite sides of the middle area 703. The middle area 703 includes a third upper layer 703a, a third middle layer 703b, a middle partition 703c and a third lower layer 703d arranged in sequence. The circuit board assembly 8 includes a middle substrate 85. The middle substrate 85 is disposed in the third middle layer 703b. A part of the first upper substrate 81 is disposed in the third upper layer 703a, and a part of the first lower substrate 83 is disposed in the third lower layer 703d. The middle area 703 is a third multi-layer structure formed by a part of the first upper substrate 81, the middle substrate 85, the middle partition 703c and a part of the first lower substrate 83, such as a four-layer structure. Since the space of the middle area 703 is effectively utilized, the space utilization is enhanced and the power density is increased. In an embodiment, some of electronic components 9 are disposed on the middle substrate 85, so that the space utilization is enhanced and the power density is increased.

As shown in FIG. 9 and FIG. 10, in the present embodiment, the circuit board assembly 8 includes a first lateral substrate 86. The first lateral substrate 86 is disposed at a side of the first heat dissipating area 701, and perpendicularly connected between the first upper substrate 81 and the first lower substrate 83. The first upper substrate 81 and the first lower substrate 83 are electrically connected with each other through the first lateral substrate 86. Consequently, the accommodation space 70 inside the housing 7 is effectively utilized, and the space utilization is enhanced, the volume is reduced and the power density is increased. In an embodiment, some of the plurality of electronic components 9 are disposed on the first lateral substrate 86 for enhancing the space utilization and increasing the power density.

As shown in FIG. 9 and FIG. 10, in the present embodiment, the circuit board assembly 8 includes a second lateral substrate 87. The second lateral substrate 87 is disposed between the middle area 703 and the second heat dissipating area 702, and perpendicularly connected between the first upper substrate 81 and the first lower substrate 83. The first upper substrate 81 and the first lower substrate 83 are electrically connected with each other through the second lateral substrate 87. The middle substrate 85 is electrically connected with the first upper substrate 81. In an embodiment, some of the plurality of electronic components 9 are disposed in the second lateral substrate 87 and/or the middle substrate 85 for enhancing the space utilization and increasing the power density.

As shown in FIG. 9 and FIG. 10, in the present embodiment, the plurality of electronic components 9 include a first group 91, a second group 92, a third group 93, a fourth group 94 and a fifth group 95. The first group 91 is disposed on the first upper substrate 81, and corresponding to the first upper layer 701a. In the present embodiment, the first group 91 includes the electronic components having lower height, for example but not limited to include at least one power component. In an embodiment, the at least one power component is a power transistor, wherein the power transistor can be either a discrete type or an integrated type. The second group 92 is disposed on the first lower substrate 83, and corresponding to the first lower layer 701b. In the present embodiment, the second group 92 includes the electronic components having higher height, for example but not limited to include a transformer and an inductor. The third group 93 is disposed on the second upper substrate 82, and corresponding to the second upper layer 702a. In the present embodiment, the third group 93 includes the electronic components having medium heights, for example but not limited to include at least one magnetic component. In an embodiment, the at least one magnetic component includes a common mode inductor and a differential mode inductor. The fourth group 94 is disposed on the second lower substrate 84, and corresponding to the second lower layer 702b. In the present embodiment, the fourth group 94 includes the electronic components having medium height, for example but not limited to include a capacitor and a common mode inductor. The fifth group 95 is disposed on the first lower substrate 83, and corresponding to the third lower layer 703d. In an embodiment, the fifth group 95 includes an aluminum electrolytic capacitor. As mentioned above, the electronic components 9 are arranged and disposed in the layers and the areas according to the heights and the heat dissipating requirements thereof, so that the accommodation space 70 inside the housing 7 is effectively utilized. Consequently, the space utilization is enhanced, the volume is reduced and the power density is increased.

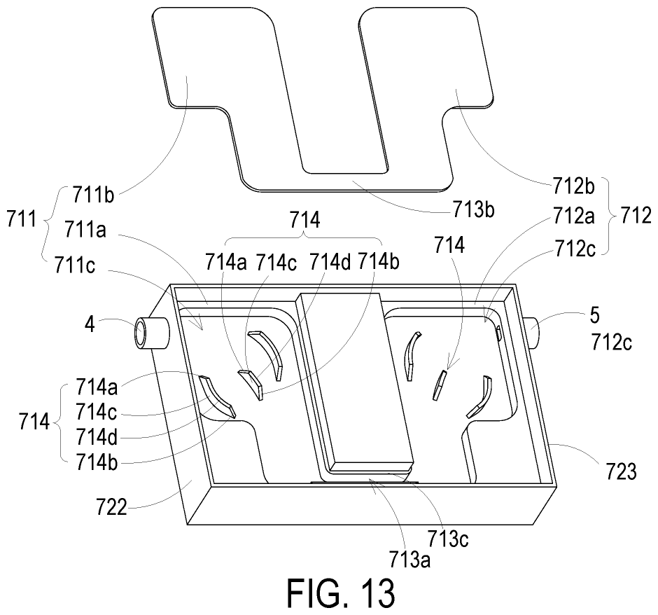

As shown in FIG. 8 to FIG. 11, the first fluid channel layer 711 and the second fluid channel layer 712 of the on-board charger 102 include a plurality of fluid guiding units (not shown in FIG. 8 to FIG. 11), respectively. The plurality of fluid guiding units are similar to the fluid guiding unit 714 shown in the FIG. 13 to FIG. 15. Component parts and elements corresponding to those of the fourth embodiment are designated by identical numeral references, and detailed descriptions thereof are omitted.

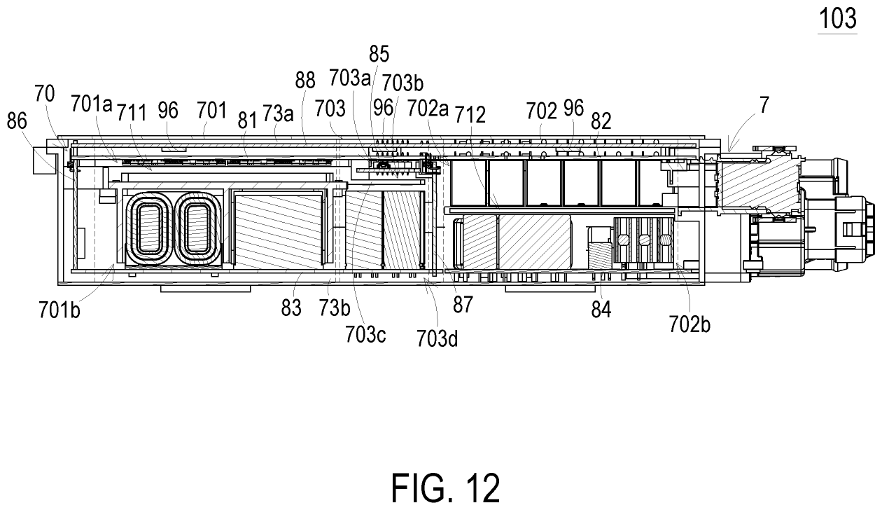

FIG. 12 is a cross-sectional view illustrating the on-board charger according to a fifth embodiment of the present disclosure. The on-board charger 103 of the present embodiment is similar to the on-board charger 101 shown in FIG. 8 to FIG. 11. Component parts and elements corresponding to those of the fourth embodiment are designated by identical numeral references, and detailed descriptions thereof are omitted. Different from the on-board charger 101 shown in FIG. 8 to FIG. 11, the circuit board assembly 8 of the on-board charger 103 includes a third upper substrate 88. The third upper substrate 88 is disposed at a side of the first upper substrate 81 and the second upper substrate 82. A part of the third upper substrate 88 is disposed in the first upper layer 701a, and a part of the third upper substrate 88 is disposed in the second upper layer 702a. A part of the third upper substrate 88, a part of the first upper substrate 81, the first fluid channel layer 711 and a part of the first lower substrate 83 collectively form a first multi-layer structure, such as a first four-layer structure. A part of the third upper substrate 88, the second upper substrate 82, the second fluid channel layer 712 and the second lower substrate 84 collectively form a second multi-layer structure, such as a second four-layer structure. In some other embodiments, the on-board charger 103 includes a middle area 703. A part of the third upper substrate 88 is disposed in the third upper layer 703a, a part of the third upper substrate 88, a part of the first upper substrate 81, the middle substrate 85, the middle partition 703c and a part of the first lower substrate 83 collectively form a third multi-layer structure, such as a first five-layer structure. Due to the arrangement of the first multi-layer structure, the second multi-layer structure and the third multi-layer structure, the accommodation space 70 of the housing 7 is effectively utilized. Consequently, the space utilization is enhanced and the power density is increased.

As shown in FIG. 12, in the present embodiment, the plurality of electronic components 9 include a sixth group 96. The sixth group 96 is disposed on the third upper substrate 88, and corresponding to the first upper layer 701a, the second upper layer 702a and/or the third upper layer 703a. In the present embodiment, the sixth group 96 includes the electronic components having lower heights, for example but not limited to include a control chip and a communication chip. In an embodiment, the control chip is a digital signal processor (DSP), and the communication chip is a microprocessor control unit (MCU). Due to the arrangement of the third upper substrate 88, additional electronic components 9 can be disposed inside the on-board charger 103, and the electronic components 9 are arranged and disposed in the layers and the areas according to the heights and heat dissipating requirements thereof. Consequently, the accommodation space 70 of the housing 7 are effectively utilized, the space utilization is enhanced, the volume is reduced and the power density is increased.

In the embodiment as shown in FIG. 1 to FIG. 5, the circuit board assembly 3 of the on-board charger 100 may include a third upper substrate (not shown). The structure and function of the third upper substrate 88 of the on-board charger 103 of this embodiment are similar to that of the third upper substrate of the on-board charger 100 shown in FIG. 1 to FIG. 5, and are not be repeatedly described hereinafter.

FIG. 13 is an exploded view illustrating a housing of an on-board charger according to a sixth embodiment of the present disclosure. The on-board charger of the present embodiment is similar to the on-board charger 102 shown in FIG. 8 to FIG. 11. Component parts and elements corresponding to those of the fourth embodiment are designated by identical numeral references, and detailed descriptions thereof are omitted. Different from the on-board charger 102 shown in FIG. 8 to FIG. 11, the connection channel 710c of the present embodiment includes a third fluid channel 713c. The first sidewall 721 of the plurality of the sidewalls 72 of this embodiment omits an inlet channel and an outlet channel. As shown in FIG. 13, in the present embodiment, the inlet fluid connector 4 is disposed on the second sidewall 722 of the plurality of sidewalls 72, and the outlet fluid connector 5 is disposed on the third sidewall 723 of the plurality of sidewalls 72. The second sidewall 722 and the third sidewall 723 are disposed opposite to each other. Since the inlet fluid connector 4 and the outlet fluid connector 5 are disposed on two opposite sides of the housing 7, the width of the housing 7 is further reduced. Consequently, the volume is reduced and the power density is increased. In the present embodiment, the inlet fluid connector 4 is directly in fluid communication with the first fluid channel 711c, and the outlet fluid connector 5 is directly in fluid communication with the second fluid channel 712c. Under this circumstance, additional inlet channel and outlet channel are unnecessary. Consequently, the structure of the on-board charger is simple, is easy to be manufactured, and has lower cost.

In the present embodiment, the first fluid channel layer 711 and the second fluid channel layer 712 include a plurality of fluid guiding units 714, respectively. The plurality of fluid guiding units 714 are configured to guide fluid to fully pass through the first fluid channel 711c and the second fluid channel 712c and increase the heat exchanging area of the fluid. The plurality of fluid guiding units 714 of the first fluid channel layer 711 are extended from the first base 711a of the first fluid channel layer 711 toward the first fluid channel 711c, and the plurality of fluid guiding units 714 of the second fluid channel layer 712 are extended from the second base 712a of the second fluid channel layer 712 toward the second fluid channel 712c. Due to the arrangement of the plurality of fluid guiding units 714, the fluid is guided to fully pass through the first fluid channel 711c and the second fluid channel 712c. Consequently, the heat exchanging area of the fluid is increased, and the heat dissipation efficiency is increased.

As shown in FIG. 13, each of the fluid guiding units 714 is an elongational sheet structure and has a first end 714a, a second end 714b, a first surface 714c and a second surface 714d. The first end 714a and the second end 714b are two opposite ends of the fluid guiding unit 714. The first surface 714c and the second surface 714d are two opposite surfaces of the fluid guiding unit 714, and in connection between the first end 714a and the second end 714b, respectively. In the present embodiment, the plurality of fluid guiding units 714 are disposed in parallel (i.e. side by side), and the first surface 714c of each of the fluid guiding units 714 is disposed toward the second surface 714d of one adjacent fluid guiding unit 714. In the present embodiment, the first surface 714c and the second surface 714d of the fluid guiding unit 714 are for example, but not limited to curved surfaces, respectively. In some embodiments, the first surface 714c and the second surface 714d of the fluid guiding unit 714 are selected from at least one of a carved surface and a flat surface. Since the plurality of fluid guiding units 714 are disposed in parallel (i.e. side by side), the fluid is guided to fully pass through the first fluid channel 711c and the second fluid channel 712c. Consequently, the heat dissipation efficiency is increased.

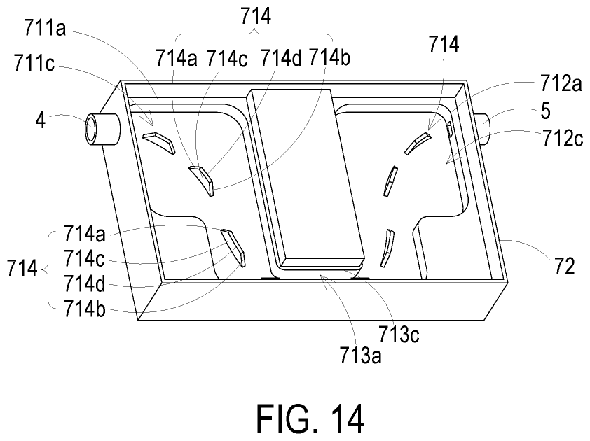

FIG. 14 is an exploded view illustrating a housing of an on-board charger according to a seventh embodiment of the present disclosure, wherein a first cover, a second cover and a third cover are omitted. The on-board charger of the present embodiment is similar to the on-board charger shown in FIG. 13. Component parts and elements corresponding to those of the sixth embodiment are designated by identical numeral references, and detailed descriptions thereof are omitted. Different from the on-board charger shown in FIG. 13, the plurality of fluid guiding units 714 of the present embodiment are arranged in series. The first end 714a of each of the fluid guiding units 714 is disposed corresponding to the second end 714b of one adjacent fluid guiding unit 714. Since the plurality of fluid guiding units 714 are disposed in series, the fluid is guided to fully pass through the first fluid channel 711c and the second fluid channel 712c. Consequently, the heat dissipation efficiency is increased.

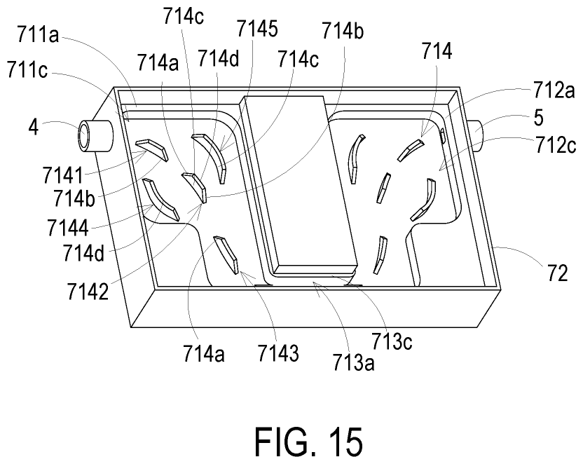

FIG. 15 is an exploded view illustrating a housing of an on-board charger according to an eighth embodiment of the present disclosure, wherein a first cover, a second cover and a third cover are hided. The on-board charger of the present embodiment is similar to the on-board charger shown in FIG. 13. Component parts and elements corresponding to those of the sixth embodiment are designated by identical numeral references, and detailed descriptions thereof are omitted. Different from the on-board charger shown in FIG. 13, at least a part of the fluid guiding units 714 of the present embodiment are disposed in parallel (i.e. side by side), and at least a part of the fluid guiding units 714 are arranged in series, but not limited thereto. As shown in the first fluid channel layer 711 of FIG. 15, the plurality of fluid guiding units 714 disposed in the first fluid channel layer 711 include a first fluid guiding unit 7141, a second fluid guiding unit 7142, a third fluid guiding unit 7143, a fourth fluid guiding unit 7144 and a fifth fluid guiding unit 7145. The second end 714b of the first fluid guiding unit 7141 is disposed corresponding to the first end 714a of the second fluid guiding unit 7142. The second end 714b of the second fluid guiding unit 7142 is disposed corresponding to the first end 714a of the third fluid guiding unit 7143. In other words, the first fluid guiding unit 7141, the second fluid guiding unit 7142 and the third fluid guiding unit 7143 are arranged in series. The second surface 714d of the fourth fluid guiding unit 7144 is disposed toward the first surface 714c of the second fluid guiding unit 7142. The second surface 714d of the second fluid guiding unit 7142 is disposed toward the first surface 714c of the fifth fluid guiding unit 7145. In other words, the fourth fluid guiding unit 7144, the second fluid guiding unit 7142 and the fifth fluid guiding unit 7145 are disposed in parallel (i.e. side by side). Since at least a part of the fluid guiding units 714 are disposed in parallel (i.e. side by side) and at least a part of the fluid guiding units 714 are arranged in series, the fluid is guided to fully pass through the first fluid channel 711c and the second fluid channel 712c. Consequently, the heat dissipation efficiency is increased. In an embodiment, the arrangement of the plurality of fluid guiding units 714 is an irregular arrangement.

From the above descriptions, the present disclosure provides an on-board charger. The electronic components of the on-board charger are arranged in the layers and the areas according to the heights and the heat dissipating requirements thereof. Consequently, the space utilization is enhanced, the volume is reduced and the power density is increased. Due to the arrangement of the plurality of substrates of the circuit board assembly, the accommodation space of the housing is effectively utilized. Consequently, the space utilization is enhanced, the volume is reduced and the power density is increased. In addition, since the inlet channel and the outlet channel are formed inside the housing, additional flow channels are omitted to save the space. Since a modular structure is formed through the electronic components and the first cover of the fluid channel heat dissipating area, the area and integrity of heat dissipating is increased. Since the inlet fluid connector and the outlet fluid connector are arranged side by side, or are disposed opposite side relative to the at least one electrical connector, the width of the housing is reduced. Consequently, the volume of the on-board charger is reduced, and the power density is increased.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An on-board charger, comprising:
a housing comprising a plurality of sidewalls, wherein the plurality of sidewalls are connected with each other to define an accommodation space, wherein the accommodation space comprises a first heat dissipating area, the first heat dissipating area comprises a first upper layer, a first fluid channel layer and a first lower layer, the first fluid channel layer is disposed between the first upper layer and the first lower layer and comprises a first base, a first cover and a first fluid channel, the first cover covers the first base to form the first fluid channel;
a connection channel in communication with the first fluid channel, wherein the connection channel and the first base are integrally formed into a one-piece structure;
a circuit board assembly comprising a first upper substrate and a first lower substrate, wherein at least a part of the first upper substrate is disposed in the first upper layer, and at least a part of the first lower substrate is disposed in the first lower layer; and
a plurality of electronic components disposed corresponding to the circuit board assembly.

2. The on-board charger according to claim 1, wherein the connection channel comprises an inlet channel and an outlet channel, the inlet channel and the outlet channel are disposed side by side inside a first sidewall of the plurality of sidewalls, wherein the first base is extended from the first sidewall toward the first heat dissipating area, and wherein the on-board charger further comprising an inlet fluid connector and an outlet fluid connector, the inlet fluid connector and the outlet fluid connector are disposed side by side on the second sidewall of the plurality of sidewalls, and the second sidewall is adjacently connected with the first sidewall, wherein the inlet channel is in communication with the inlet fluid connector, and the outlet channel is in communication with the outlet fluid connector.

3. The on-board charger according to claim 2, wherein the first base comprises a groove and a separation part, the separation part is disposed in the groove, the groove is divided into two channels which are interconnected by the separation part, and the two channels are in communication with the inlet channel and the outlet channel, respectively, wherein the first cover covers the groove to seal the two channels and to form the first fluid channel.

4. The on-board charger according to claim 1, wherein the accommodation space comprises a second heat dissipating area, wherein the second heat dissipating area is disposed at a side of the first heat dissipating area, and comprises a second fluid channel layer, wherein the second fluid channel layer comprises a second base, a second cover and a second fluid channel, wherein the second cover covers the second base to form the second fluid channel of the second fluid channel layer, wherein the accommodation space comprises a third fluid channel layer, the third fluid channel layer comprises a third base, a third cover and a third fluid channel, wherein the third cover covers the third base to form the third fluid channel of the third fluid channel layer, the third fluid channel is in communication between the first fluid channel and the second fluid channel to form a fluid flowing path, wherein the connection channel includes the third fluid channel; wherein the first base, the second base and the third base are integrally formed into a first one-piece structure, and/or wherein the first cover, the second cover and the third cover are integrally formed into a second one-piece structure.

5. The on-board charger according to claim 4, further comprising an inlet fluid connector and an outlet fluid connector, wherein the inlet fluid connector is in communication with the first fluid channel, the outlet fluid connector is in communication with the second fluid channel, wherein the inlet fluid connector and the outlet fluid connector are disposed on a second sidewall and a third sidewall of the plurality of sidewalls, respectively, wherein the second sidewall and the third sidewall are disposed opposite to each other.

6. The on-board charger according to claim 4, wherein the connection channel includes an inlet channel and an outlet channel, the inlet channel and the outlet channel are disposed side by side inside a first sidewall of the plurality of sidewalls, wherein the first base is extended from the first sidewall toward the first heat dissipating area, and the second base is extended from the first sidewall toward the second heat dissipating area, wherein the inlet channel is in communication with the second fluid channel, and the outlet channel is in communication with the first fluid channel, and wherein the on-board further comprising an inlet fluid connector and an outlet fluid connector, wherein the inlet fluid connector and the outlet fluid connector are disposed side by side on the second sidewall of the plurality of sidewalls, and the second sidewall is adjacently connected with the first sidewall, wherein the inlet channel is in communication with the inlet fluid connector, and the outlet channel is in communication with the outlet fluid connector.

7. The on-board charger according to claim 4, wherein the first base is disposed perpendicular to the first sidewall, and/or the second base is disposed perpendicular to the first sidewall.

8. The on-board charger according to claim 4, wherein the first fluid channel layer, the second fluid channel layer and the third fluid channel layer are coplanar.

9. The on-board charger according to claim 4, wherein the first fluid channel layer and the second fluid channel layer are non-coplanar, wherein the third fluid channel layer is inclined from the first fluid channel layer toward the second fluid channel layer, or the third fluid channel layer is inclined from the second fluid channel layer toward the first fluid channel layer.

10. The on-board charger according to claim 4, wherein the first fluid channel layer comprises a plurality of fluid guiding units, the plurality of fluid guiding units of the first fluid channel layer are extended from the first base toward the first fluid channel, and/or the second fluid channel layer comprises a plurality of fluid guiding units, the plurality of fluid guiding units of the second fluid channel layer are extended from the second base toward the second fluid channel, wherein each of the plurality of fluid guiding units is an elongational sheet structure and has a first end, a second end, a first surface and a second surface, wherein the first end and the second end are two opposite ends of the fluid guiding unit, wherein the first surface and the second surface are two opposite surfaces of the fluid guiding unit, and in connection between the first end and the second end, respectively, wherein the plurality of fluid guiding units are arranged in series, in parallel or a combination thereof, wherein the plurality of fluid guiding units are arranged in series by disposing the first end of each of the fluid guiding unit to correspond to the second end of one adjacent fluid guiding unit, wherein the plurality of fluid guiding units are arranged in parallel by disposing the first surface of each of the fluid guiding unit toward the second surface of adjacent fluid guiding unit, wherein the first surface and the second surface of the fluid guiding unit are selected from at least one of a flat surface and a curved surface.

11. The on-board charger according to claim 1, wherein the circuit board assembly includes a second upper substrate and a second lower substrate, and the accommodation space comprises a second heat dissipating area, wherein the second heat dissipating area is disposed at a side of the first heat dissipating area, and comprises a second upper layer, a heat dissipating layer and a second lower layer, wherein the heat dissipation layer is disposed between the second upper layer and the second lower layer, the second upper substrate is disposed in the second upper layer, and the second lower substrate is disposed in the second lower layer, wherein the heat dissipating layer is a fluid channel layer or a partition layer.

12. The on-board charger according to claim 11, wherein the first upper substrate and the second upper substrate are integrally formed into a one-piece circuit board, and/or the first lower substrate and the second lower substrate are integrally formed into a one-piece circuit board.

13. The on-board charger according to claim 11, wherein the circuit board assembly comprises a third upper substrate, the third upper substrate is disposed at a side of the first upper substrate and the second upper substrate, a part of the third upper substrate is disposed in the first upper layer, and a part of the third upper substrate is disposed in the second upper layer, wherein a part of the third upper substrate, at least of a part of the first upper substrate, the first fluid channel layer and at least of a part of the first lower substrate collectively form a first four-layer structure, wherein a part of the third upper substrate, the second upper substrate, the heat dissipating layer and the second lower substrate collectively form a second four-layer structure.

14. The on-board charger according to claim 13, wherein the accommodation space comprises a middle area, the first heat dissipating area and the second heat dissipating area are respectively disposed at opposite sides of the middle area, respectively, wherein the middle area comprises a third upper layer, a third middle layer, a middle partition and a third lower layer arranged in sequence, wherein the circuit board assembly comprises a middle substrate, the middle substrate is disposed in the third middle layer, a part of the third upper substrate and a part of the first upper substrate are disposed in the third upper layer, a part of the first lower substrate is disposed in the third lower layer, wherein a part of the third upper substrate, a part of the first upper substrate, the middle substrate, the middle partition and a part of the first lower substrate collectively form a first five-layer structure.

15. The on-board charger according to claim 14, wherein the circuit board assembly comprises a first lateral substrate and a second lateral substrate, wherein the first lateral substrate is disposed at a side of the first heat dissipating area, and perpendicularly connected between the first upper substrate and the first lower substrate, wherein the second lateral substrate is disposed between the middle area and the second heat dissipating area, and perpendicularly connected between the first upper substrate and the first lower substrate, wherein the middle substrate is electrically connected with the first upper substrate.

16. The on-board charger according to claim 15, wherein the plurality of electronic components comprises a first group, a second group, a third group, a fourth group, a fifth group and a sixth group, wherein the first group is disposed on the first upper substrate, and corresponding to the first upper layer, wherein the second group is disposed on the first lower substrate, and corresponding to the first lower layer, wherein the third group is disposed on the second upper substrate, and corresponding to the second upper layer, wherein the fourth group is disposed on the second lower substrate, and corresponding to the second lower layer, wherein the fifth group is disposed on the first lower substrate, and corresponding to the third lower layer, wherein the sixth group is disposed on the third upper substrate, and corresponding to the first upper layer, the second upper layer and/or the third upper layer, wherein the first group comprises at least one power component, the at least one power component is a power transistor, wherein the second group comprises at least one magnetic component, and the at least one magnetic component comprises a transformer and an inductor, wherein the third group comprises at least one magnetic component, and the at least one magnetic component comprises a common mode inductor and a differential mode inductor, wherein the fourth group comprises a capacitor and a common mode inductor, wherein the fifth group comprises an aluminum electrolytic capacitor, wherein the sixth group comprises a control chip and a communication chip.

17. An on-board charger, comprising:
a circuit board assembly comprising a first upper substrate, a second upper substrate, a first lower substrate, and a second lower substrate,
a housing having an accommodation space, wherein the accommodation space comprises:
a fluid channel dissipating area comprising a first upper layer, a fluid channel layer and a first lower layer, the fluid channel layer is disposed between the first upper layer and the first lower layer, wherein at least a part of the first upper substrate of the circuit board assembly is disposed in the first upper layer, and at least a part of the first lower substrate is disposed in the first lower layer, wherein at least a part of the first upper substrate, the fluid channel layer and at least a part of the first lower substrate collectively form a first three-layer structure; and
a partition heat dissipating area disposed at a side of the fluid channel heat dissipating area, and comprising a second upper layer, a partition layer and a second lower layer, wherein the partition layer is disposed between the second upper layer and the second lower layer, wherein the second upper substrate is disposed in the second upper layer, and the second lower substrate is disposed in the second lower layer, wherein the second upper substrate, the partition layer and the second lower substrate collectively form a second three-layer structure; and
a plurality of electronic components disposed on the circuit board assembly, respectively, and are disposed corresponding to the first upper layer, the first lower layer, the second upper layer and the second lower layer.

18. The on-board charger according to claim 17, wherein the first upper layer has a first height, the first lower layer has a second height, the second upper layer has a third height, and the second lower layer has a fourth height, wherein the second height is greater than the first height, wherein the third height is greater than the first height, and less than the second height, wherein the fourth height is greater than the first height, and less than the second height.

19. The on-board charger according to claim 18, wherein the fluid channel layer has a fluid channel layer height, and the partition layer has a partition layer height, wherein the sum of the first height, the fluid channel layer height and the second height is equal to the sum of the third height, the partition layer height and the fourth height.

20. The on-board charger according to claim 17, wherein the housing comprises an upper cover and a lower cover, the upper cover covers the top of the housing, and the lower cover covers the bottom of the housing, wherein the fluid channel heat dissipating area is disposed adjacent to the upper cover and the lower cover, and the partition heat dissipating area is disposed adjacent to the upper cover and the lower cover, the fluid channel heat dissipating area is the first three-layer structure formed by at least a part of the first upper substrate, the fluid channel layer and at least a part of the first lower substrate, the partition heat dissipating area is a second three-layer structure formed by the second upper substrate, the partition layer and the second lower substrate.

21. The on-board charger according to claim 17, wherein the first upper substrate and the second upper substrate are integrally formed into a one-piece circuit board, and/or the first lower substrate and the second lower substrate are integrally formed into a one-piece circuit board.

22. The on-board charger according to claim 17, further comprising an inlet fluid connector and an outlet fluid connector, wherein the on-board charger comprises an inlet channel, a fluid channel and an outlet channel, wherein the inlet channel and the outlet channel are formed inside a first sidewall of the housing, the fluid channel is formed inside the fluid channel layer, wherein the inlet channel is in communication between the fluid channel and the inlet fluid connector, the outlet channel is in communication between the fluid channel and the outlet fluid connector.

23. The on-board charger according to claim 22, wherein the fluid channel layer comprises a base and a cover, the base is extended form the first sidewall toward the fluid channel heat dissipating area and comprises a groove and a separation part, the separation part is disposed in the groove, the groove is divided into two channels which is interconnected by the separation part, and the two channels are in communication with the inlet channel and the outlet channel, respectively, wherein the cover covers the groove to seal the two channels and to form the fluid channel, wherein the base and the first sidewall are integrally formed into a one-piece structure, and the base is disposed perpendicular to the first sidewall.

24. The on-board charger according to claim 23, wherein the cover is disposed toward the first upper layer, or wherein the cover is disposed toward the first lower layer, and comprises a substrate and a plurality of partitions, wherein a surface of the substrate covers and seals the groove of the base, wherein the plurality of partitions are extended from the other surface of the substrate toward the first lower layer, and at least one accommodation part is defined by the substrate and the plurality of partitions, wherein the plurality of electronic components disposed in the first lower layer are modularly disposed in the at least one accommodation part of the cover.

25. The on-board charger according to claim 22, further comprising at least one electrical connector, wherein the at least one electrical connector is disposed on a second sidewall and electrically connected with the circuit board assembly, wherein the inlet fluid connector and the outlet fluid connector are disposed side by side on the second sidewall of the housing, and are disposed adjacent to the at least one electrical connector, wherein the second sidewall is adjacently connected with the first sidewall.

26. The on-board charger according to claim 22, further comprising at least one electrical connector, wherein the at least one electrical connector is disposed on a second sidewall of the housing, and electrically connected with the circuit board assembly, wherein the inlet fluid connector and the outlet fluid connector are disposed side by side on a third sidewall of the housing, wherein the second sidewall is adjacently connected with the first sidewall, wherein the third sidewall is adjacently connected with the first sidewall, and disposed opposite to the second sidewall.

27. The on-board charger according to claim 17, wherein the accommodation space further comprises a middle area, the fluid channel heat dissipating area and the partition heat dissipating area are disposed at two opposite sides of the middle area, respectively, wherein the middle area comprises a third upper layer, a third middle layer, a middle partition and a third lower layer arranged in sequence, wherein the circuit board assembly comprises a middle substrate, the middle substrate is disposed in the third middle layer, wherein a part of the first upper substrate is disposed in the third upper layer, a part of the first lower substrate is disposed in the third lower layer, wherein the middle area is a four-layer structure formed by a part of the first upper substrate, the middle substrate, the middle partition and a part of the first lower substrate.

28. The on-board charger according to claim 27, wherein the circuit board assembly includes a first lateral substrate and a second lateral substrate, wherein the first lateral substrate is disposed at a side of the fluid channel heat dissipating area, and perpendicularly connected between the first upper substrate and the first lower substrate, wherein the second lateral substrate is disposed between the middle area and the partition heat dissipating area, and perpendicularly connected between the first upper substrate and the first lower substrate, wherein the middle substrate is electrically connected with the first upper substrate.

29. The on-board charger according to claim 17, wherein the plurality of electronic components comprises a first group, a second group, a third group and a fourth group, wherein the first group is disposed on the first upper substrate, and corresponding to the first upper layer, wherein the second group is disposed on the first lower substrate, and corresponding to the first lower layer, wherein the third group is disposed on the second upper substrate, and corresponding to the second upper layer, wherein the fourth group is disposed on the second lower substrate, and corresponding to the second lower layer, wherein the first group comprises at least one power component, the at least one power component comprises a power transistor, wherein the second group comprises at least one magnetic component, and the at least one magnetic component comprises a transformer and an inductor, wherein the third group comprises at least one magnetic component, and the at least one magnetic component comprises a common mode inductor and a differential mode inductor, wherein the fourth group comprises a capacitor and a common mode inductor, wherein the second group is disposed on the first lower substrate toward the fluid channel layer, the third group is disposed on the second upper substrate toward the partition layer, and the fourth group is disposed on the second lower substrate toward the partition layer.

30. The on-board charger according to claim 27, wherein the plurality of electronic components comprises a fifth group, wherein the fifth group is disposed on the first lower substrate, and corresponding to the third lower layer, wherein the fifth group comprises an aluminum electrolytic capacitor.
